(19) United States
(12) Patent Application Publication
(10) Pub. No.: US 2012/0258561 A1
(43) Pub. Date: Oct. 11, 2012

(54) Low-Temperature Method for Forming Amorphous Semiconductor Layers

(75) Inventors: Jian Li, Fremont, CA (US); Venkatesan Murali, San Jose, CA (US); Yonghua Liu, Irving, TX (US); Dong Xu, San Jose, CA (US)

(73) Assignee: TWIN CREEKS TECHNOLOGIES, INC., San Jose, CA (US)

(21) Appl. No.: 13/083,625

(22) Filed: Apr. 11, 2011

(51) Int. Cl. H01L 31/02; H01L 31/0368; H01L 31/0376

(52) U.S. Cl. 438/64; 438/96; 438/97; 257/E31.047; 257/E31.043; 257/E31.11

(57) ABSTRACT

In embodiments of the present invention an undoped amorphous, nanocrystalline or microcrystalline semiconductor layer and a heavily doped amorphous, nanocrystalline, or microcrystalline semiconductor layer are formed on a monocrystalline silicon lamina. The lamina is the base region of a photovoltaic cell, while the amorphous, nanocrystalline or monocrystalline layers serve to passivate the surface of the lamina, reducing recombination at this surface. In embodiments, the heavily doped layer additionally serves as either the emitter of the cell or to provide electrical contact to the base layer. The undoped and heavily doped layers are deposited at low temperature, for example about 150 degrees C. or less with hydrogen dilution. This low temperature allows use of low-temperature materials and methods, while increased hydrogen dilution improves film quality and/or conductivity.

### BACKGROUND OF THE INVENTION

The invention relates to a low-temperature method for forming amorphous, nanocrystalline, or microcrystalline semiconductor layers.

A conventional prior art photovoltaic cell includes a p-n diode. An example is shown in FIG. 1. A depletion zone forms at the p-n junction, creating an electric field. Incident photons (incident light is indicated by arrows) will knock electrons from the valence band to the conduction band, creating free electron-hole pairs. Within the electric field at the p-n junction, electrons tend to migrate toward the n region of the diode, while holes migrate toward the p region, resulting in current, called photocurrent. Typically the dopant concentration of one region will be higher than that of the other, so the junction is either a p+/n− junction (as shown in FIG. 1) or a n+/p− junction. The more lightly doped region is known as the base of the photovoltaic cell, while the more heavily doped region, of opposite conductivity type, is known as the emitter. Most carriers are generated within the base, and it is typically the thickest portion of the cell. The base and emitter together form the active region of the cell. The cell also frequently includes a heavily doped contact region in electrical contact with the base, and of the same conductivity type, to improve current flow. In the example shown in FIG. 1, the heavily doped contact region is n-type.

Sivaram et al., U.S. Pat. No. 7,842,585, owned by the assignee of the present invention, describes a fabrication method for a photovoltaic cell involving a thin lamina. Some novel fabrication methods may benefit from reducing processing temperature.

### SUMMARY OF THE INVENTION

The present invention is defined by the following claims, and nothing in this section should be taken as a limitation on those claims. In general, the invention is directed to a low-temperature method to form thin amorphous, nanocrystalline, or microcrystalline semiconductor layers suitable for use in a photovoltaic cell.

A first aspect of the invention provides for a method for forming a device, the method comprising: providing a monocrystalline semiconductor lamina having a first surface and a second surface opposite the first; depositing a first undoped amorphous, nanocrystalline, or microcrystalline semiconductor layer on and in contact with the second surface of the lamina by PECVD while flowing a precursor gas, the first undoped layer having a thickness less than about 100 angstroms; depositing a second doped amorphous, nanocrystalline, or microcrystalline semiconductor layer on and in contact with the first undoped layer by PECVD while flowing the precursor gas, the second doped layer having a thickness less than about 300 angstroms, wherein, during the step of depositing the first undoped layer and the step of depositing the second doped layer, deposition temperature is less than about 150 degrees C. and a ratio of hydrogen to the precursor gas is at least 1:1; and wherein the lamina, the first undoped layer, and the second doped layer are suitable for use in a photovoltaic cell.

An embodiment of the invention provides for a method for forming a device, the method comprising: providing a monocrystalline silicon lamina having a first surface and a second surface opposite the first, the lamina having a thickness between about 1 and about 20 microns, the first surface adhered to a first support element by an adhesive; depositing a first undoped amorphous, nanocrystalline, or microcrystalline semiconductor layer on and in contact with the second surface of the lamina by PECVD while flowing a precursor gas, the first undoped layer having a thickness less than about 100 angstroms; depositing a second doped amorphous, nanocrystalline, or microcrystalline semiconductor layer on and in contact with the first undoped layer by PECVD while flowing the precursor gas, the second doped layer having a thickness less than about 300 angstroms, wherein, during the step of depositing the first undoped layer and the step of depositing the second doped layer, deposition temperature is less than about 150 degrees C. and a ratio of hydrogen to the precursor gas is at least 4:1, and wherein the lamina, the first undoped layer, and the second doped layer are suitable for use in a photovoltaic cell.

Each of the aspects and embodiments of the invention described herein can be used alone or in combination with one another.

The preferred aspects and embodiments will now be described with reference to the attached drawings.

### BRIEF DESCRIPTION OF THE DRAWINGS

FIG. 1 is a cross-sectional view illustrating a prior art photovoltaic cell.

FIGS. 2a-2d are cross-sectional views showing stages in formation of the photovoltaic device of Murali et al., U.S. patent application Ser. No. 12/980,424.

FIG. 3 is a block diagram illustrating the steps of a method according to an embodiment of the present invention.

FIGS. 4a-4e are cross-sectional views showing stages in formation of a photovoltaic cell according to an embodiment of the present invention.

### DETAILED DESCRIPTION OF THE EMBODIMENTS

Murali et al., U.S. patent application Ser. No. 12/980,424, “A Method to Form a Device by Constructing a Support Element on a Thin Semiconductor Lamina,” owned by the assignee of the present invention and hereby incorporated by reference; and Sivaram et al., cited earlier, describe fabrication of a photovoltaic cell comprising a thin semiconductor lamina formed of crystalline, non-deposited semiconductor material. Using the methods of Sivaram et al. and Murali et al., photovoltaic cells, rather than being formed from sliced wafers, are formed of thin semiconductor laminae without wasting silicon through kerf loss or by fabrication of an unnecessarily thick cell, thus reducing cost. The same donor wafer can be reused to form multiple laminae, further reducing cost, and may be resold after exfoliation of multiple laminae for some other use.

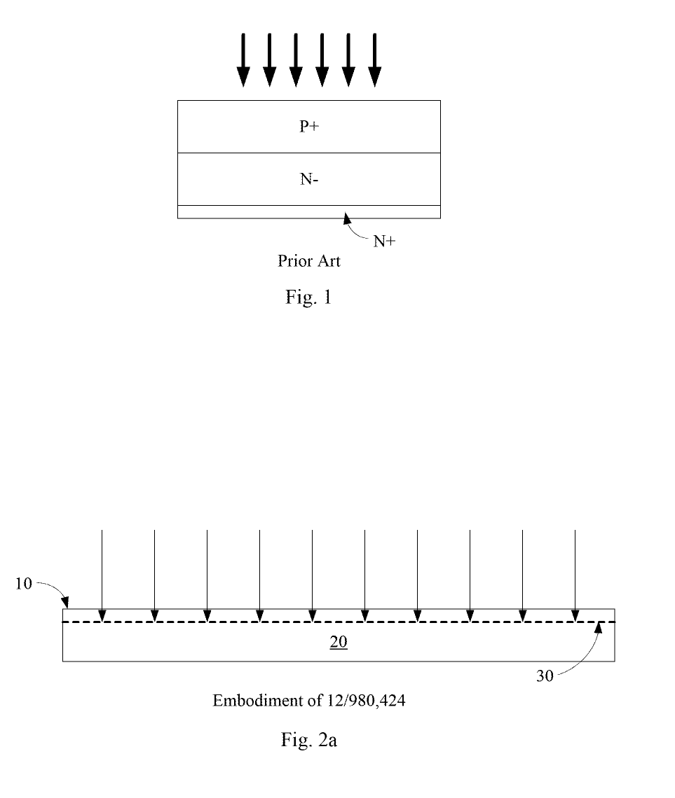

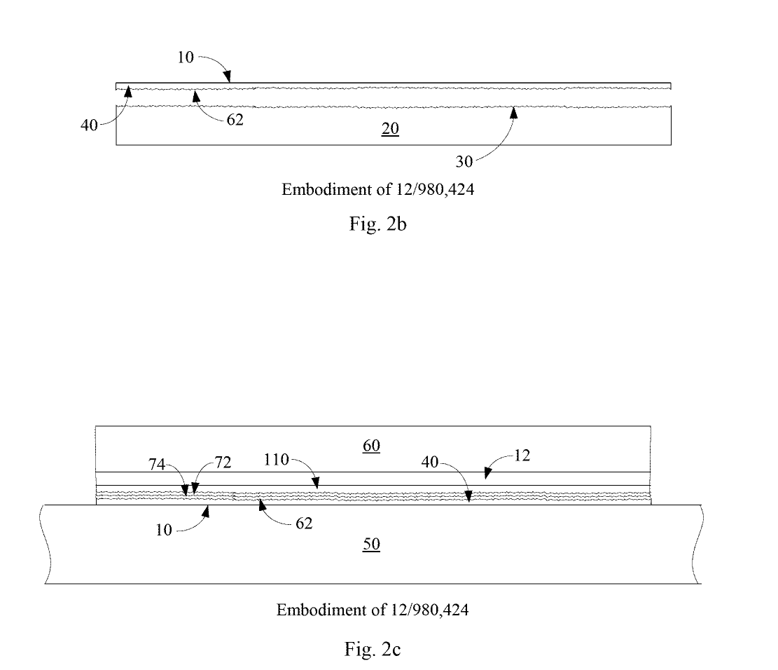

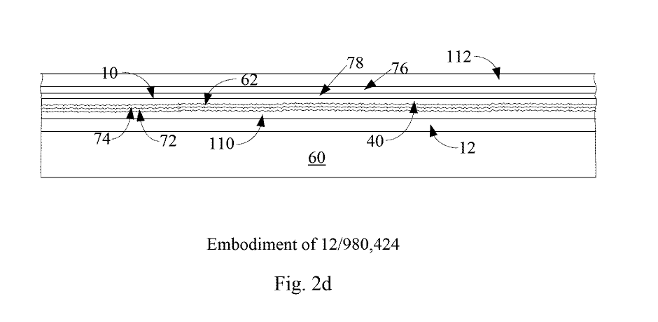

Referring to FIG. 2a, in embodiments of Murali et al., a monocrystalline semiconductor donor wafer 20 is implanted through first surface 10 to form cleave plane 30. As shown in FIG. 2b, a heating step is performed and lamina 40 separates from the donor wafer at the cleave plane, creating second surface 62. Referring to FIGS. 2a and 2b, note that during the cleaving step, first surface 10 of the donor wafer is not permanently affixed to a support element. In some embodiments, first surface 10 may be affixed to a temporary support such as an electrostatic chuck (not shown).

Cleaving is most easily achieved by heating, for example to temperatures of 400 degrees C. or more. It has been found that the step of implanting to define the cleave plane may cause damage to the crystalline lattice of the monocrystalline donor wafer. This damage, if unrepaired, may impair cell efficiency. A relatively high-temperature anneal of the lamina following cleaving, for example at 900 degrees C., 950 degrees C., or more, will repair most implant damage in the body of the lamina.

Following this anneal, lamina 40 may be transferred and affixed to a temporary support element 50, as shown in FIG. 2c. As will be described in additional detail, one or more layers, including, for example, deposited semiconductor layers 74 and 72, transparent conductive oxide (TCO) layer 110, and reflective metal layer 12, are deposited on lamina 40. A permanent support element 60 may be constructed on lamina 40; in the embodiment shown, it is constructed directly on metal layer 12, which is formed over second surface 62 of lamina 40. Support element 60 will be made sufficiently thick to provide mechanical support to lamina 40, which is too thin and fragile to survive much handling without such support.

Turning to FIG. 2d, following construction of support element 60, lamina 40 is detached from temporary support element 50. FIG. 2d shows the structure inverted, with constructed support element 60 on the bottom, as in most embodiments. Additional layers, such as deposited semiconductor layers 78 and 76 and ITO layer 112 are deposited, forming a photovoltaic cell.

Referring to FIG. 2d, this cell includes deposited semiconductor layers 74 and 72 on one side of lamina 40 and deposited semiconductor layers 78 and 76 on the opposing surface. Layer 74, in immediate contact with one surface of lamina 40, is undoped, while layer 72, in immediate contact with undoped layer 74, is heavily doped. Similarly, layer 78, in immediate contact with the opposing surface of lamina 40, is undoped, while layer 76, in immediate contact with undoped layer 78, is heavily doped. Doped layers 72 and 76 are doped to opposite conductivity types. Lamina 40 is more lightly doped than are heavily doped silicon layers 72 and 76, and will serve as the base region of the photovoltaic cell. The base region of the cell absorbs incident light, and is where most charge carriers are generated. Lamina 40 is very thin, much thinner than the absorber region of a conventional photovoltaic cell. Thus, passivation of surfaces 10 and 62 of the lamina is particularly helpful to avoid loss of charge carriers by recombination at these surfaces. Deposited undoped semiconductor layers 74 and 78 provide effective means of passivation, and their use is particularly advantageous with a very thin absorber as in embodiments of Murali et al. In various embodiments, any of layers 72, 74, 76 and 78 may be amorphous, nanocrystalline or microcrystalline. One of heavily doped layers 72 or 76 will serve as the emitter of the cell.

Referring to FIG. 2c, in embodiments of the present invention, layers 74 and 72 are deposited on second surface 62 of lamina 40 while lamina 40 is adhered to temporary support element 50 at first surface 10 by means of an adhesive (not shown). Note that in other embodiments, the lamina may be inverted and second surface 62, rather than first surface 10, may be adhered to temporary support element 50 during this step. In the present invention, in this example, undoped semiconductor layer 74 is deposited on and immediately in contact with second surface 62 of lamina 40. Heavily doped semiconductor layer 72 is deposited on and immediately in contact with undoped semiconductor layer 74. This deposition is performed by plasma-enhanced chemical vapor deposition (PECVD) at low temperature, for example less than about 150 degrees C., in some embodiments between about 80 degrees C. and about 150 degrees C. This deposition may take place between about 90 or about 100 degrees C. and about 110 or about 120 degrees C. In general, film quality degrades and deposition rates fall when deposition temperature is decreased. It has been found, however, that increasing hydrogen dilution of the source gas during deposition tends to improve film quality, as this may compensate for thermal energy loss at lower deposition temperature.

Without wishing to be bound to any particular theory, it is thought that film quality is improved when deposition temperature is higher because the increased surface mobility of adatoms during deposition allows them to migrate and find lower-energy locations. With increased hydrogen dilution of the source gas, breaking and recombining of hydrogen may provide energy to compensate for lower-temperature deposition. In the present invention, during deposition of layers 74 and 72, hydrogen dilution of the source gas is at least 1:1, for example up to 100:1, or at any ratio in between. In embodiments, hydrogen dilution of the source gas may be between about 4:1 and about 50:1, for example between about 4:1 and about 10:1, for example about 8:1. Low-temperature deposition of undoped silicon, or other semiconductor, in this manner improves film quality, and, in the present invention, its ability to passivate the crystalline surface on which it is deposited. Low-temperature deposition of doped silicon improves conductivity of the silicon by enhancing activation of dopants.

Conventionally, plasma power density during PECVD may be about 12.5 mW/cm². In embodiments of the present invention, plasma power density during PECVD of semiconductor layers, for example silicon layers on a surface of crystalline lamina 40, may be much greater, for example between about 25 and about 200 mW/cm², for example about 125 mW/cm². Increasing plasma power density may also serve to improve film quality and/or conductivity.

An adhesive binds lamina 40 to temporary support element 50. High temperature, for example higher than about 200 degrees C., or even about 150 or 180 degrees C., will cause the adhesive to soften, which may cause lamina 40 to wrinkle or bow. This may damage the photovoltaic device to be formed. The low-temperature PECVD deposition of the present invention, combined with hydrogen dilution of the source gas, forms a high-quality deposited semiconductor film while avoiding damage to the lamina.

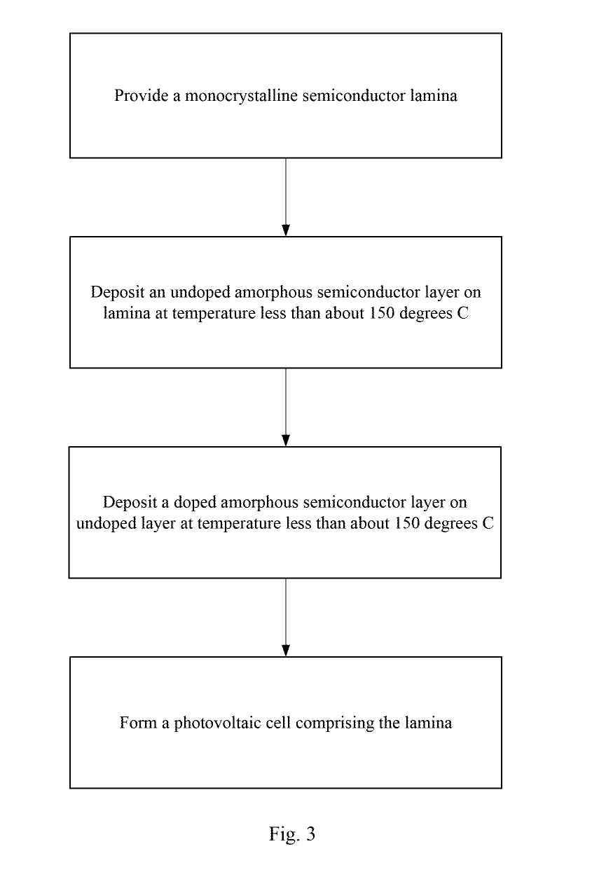

Summarizing, a method has been described for forming a photovoltaic cell. The method includes providing a monocrystalline semiconductor lamina having a first surface and a second surface opposite the first; depositing a first undoped amorphous, nanocrystalline, or microcrystalline semiconductor layer on and in contact with the second surface of the lamina by PECVD while flowing a precursor gas, the first undoped layer having a thickness less than about 100 angstroms; and depositing a second doped amorphous, nanocrystalline, or microcrystalline semiconductor layer on and in contact with the first undoped layer by PECVD while flowing the precursor gas, the second doped layer having a thickness less than about 300 angstroms. During the step of depositing the first undoped layer and the step of depositing the second doped layer, deposition temperature is less than about 150 degrees C. and a ratio of hydrogen to the precursor gas is at least 1:1. The lamina, the first undoped layer, and the second doped layer are suitable for use in a photovoltaic cell, which is then fabricated. During the step of depositing the undoped layer and the doped layer, the first surface of the lamina is adhered to a support element by an adhesive. This support element is temporary, and will not be present in the completed photovoltaic cell. The steps of this method are summarized in the block diagram of FIG. 3.

For clarity, a detailed example will be provided of a photovoltaic assembly including a lamina having thickness between 1 and 20 microns, in which amorphous, nanocrystalline, or microcrystalline layers, one undoped and one doped, are deposited on the lamina during fabrication of a photovoltaic cell. For completeness, many materials, conditions, and steps will be described. It will be understood, however, that many of these details can be modified, augmented, or omitted while the results fall within the scope of the invention.

### EXAMPLE

The process begins with a donor body of an appropriate semiconductor material. An appropriate donor body may be a monocrystalline silicon wafer of any practical thickness, for example from about 200 to about 1000 microns thick or more. Typically the wafer has a <100> orientation, though wafers of other orientations may be used. Different crystalline orientations may be selected, for example, to avoid channeling during the implant step to come. In alternative embodiments, the donor wafer may be thicker; maximum thickness is limited only by practicalities of wafer handling, and may be, for example, 10,000 microns or more. Alternatively, polycrystalline or multicrystalline silicon may be used, as may microcrystalline silicon, or wafers or ingots of other semiconductor materials, including germanium, silicon germanium, or III-V or II-VI semiconductor compounds such as GaAs, InP, etc. In this context the term multicrystalline typically refers to semiconductor material having grains that are on the order of a millimeter or larger in size, while polycrystalline semiconductor material has smaller grains, on the order of a thousand angstroms. The grains of microcrystalline semiconductor material are very small, for example 100 angstroms or so. Microcrystalline silicon, for example, may be fully crystalline or may include these microcrystals in an amorphous matrix. Multicrystalline or polycrystalline semiconductors are understood to be completely or substantially crystalline. Nanocrystalline semiconductor material includes very small crystals, 100 angstroms or less, in an amorphous matrix. It will be appreciated by those skilled in the art that the term “monocrystalline silicon” as it is customarily used will not exclude silicon with occasional flaws or impurities such as conductivity-enhancing dopants.

The process of forming monocrystalline silicon generally results in circular wafers, but the donor body can have other shapes as well. For photovoltaic applications, cylindrical monocrystalline ingots are often machined to an octagonal, or pseudosquare, cross section prior to cutting wafers. Wafers may also be other shapes, such as square. Square wafers have the advantage that, unlike circular or hexagonal wafers, they can be aligned edge-to-edge on a photovoltaic module with minimal unused gaps between them. The diameter or width of the wafer may be any standard or custom size. For simplicity this discussion will describe the use of a monocrystalline silicon wafer as the semiconductor donor body, but it will be understood that donor bodies of other types and materials can be used.

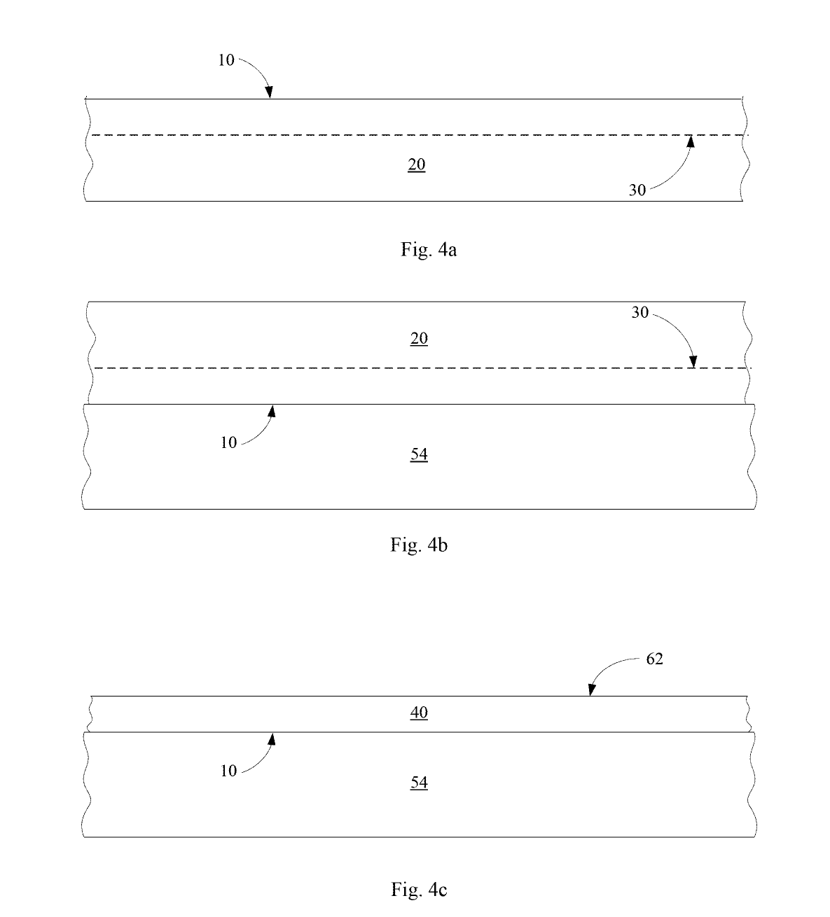

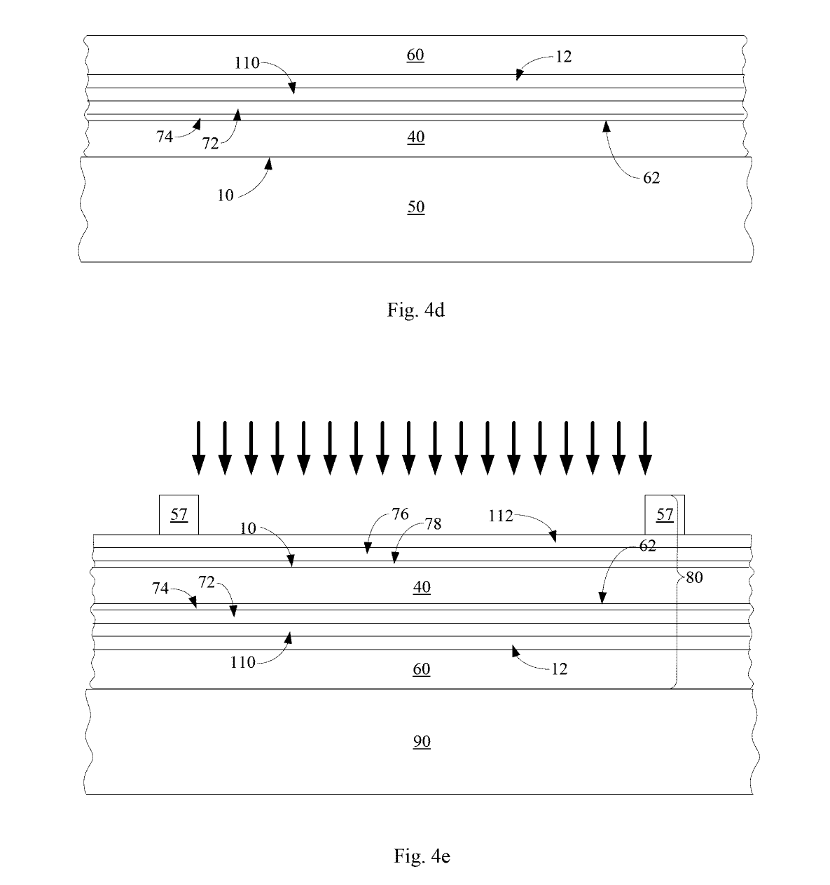

Referring to FIG. 4a, donor wafer 20 is a monocrystalline silicon wafer which is lightly to moderately doped to a first conductivity type. The present example will describe a relatively lightly n-doped wafer 20 but it will be understood that in this and other embodiments the dopant types can be reversed. Wafer 20 may be doped to a concentration of between about 1×10¹⁵ and about 1×10¹⁸ dopant atoms/cm³, for example about 1×10¹⁷ dopant atoms/cm³. Donor wafer 20 may be, for example, solar- or semiconductor-grade silicon.

In the next step, ions, preferably hydrogen or a combination of hydrogen and helium, are implanted into wafer 20 through first surface 10 to define cleave plane 30, as described earlier. This implant may be performed using the teachings of Parrill et al., U.S. patent application Ser. No. 12/122108, “Ion Implanter for Photovoltaic Cell Fabrication,” filed May 16, 2008; or those of Ryding et al., U.S. patent application Ser. No. 12/494,268, “Ion Implantation Apparatus and a Method for Fluid Cooling,” filed Jun. 30, 2009; or of Purser et al. U.S. patent application Ser. No. 12/621,689, “Method and Apparatus for Modifying a Ribbon-Shaped Ion Beam,” filed Nov. 19, 2009, all owned by the assignee of the present invention and hereby incorporated by reference. The overall depth of cleave plane 30 is determined by several factors, including implant energy. The depth of cleave plane 30 can be between about 0.2 and about 100 microns from first surface 10, for example between about 0.5 and about 20 or about 50 microns, for example between about 1 and about 10 microns, between about 1 or 2 microns and about 5 or 6 microns, or between about 4 and about 8 microns, or between about 3 and about 12 microns. Alternatively, the depth of cleave plane 30 can be between about 5 and about 15 microns, for example about 11 or 12 microns. In practice, any thickness between about 1 and about 20 microns is possible, and in some embodiments, thickness may be greater than 20 microns.

Texture (not shown) may optionally be formed at first surface 10 to minimize reflection. A method for forming advantageous low-relief texture is disclosed in Li et al., U.S. patent application Ser. No. 12/729,878, “Creation of Low-Relief Texture for a Photovoltaic Cell,” filed Mar. 23, 2010, owned by the assignee of the present invention and hereby incorporated by reference. The method of Li et al. includes buffing the surface, which may induce stress, tending to provide nucleation points for a crystallographically selective etch. Following texturing, first surface 10 has a peak-to-valley height between about 3000 angstroms and about 1 micron.

Turning to FIG. 4b, following the texture etch, first surface 10 may be placed adjacent to vacuum chuck 54, and a vacuum applied to hold donor wafer 20 in place. Vacuum chuck 54 and donor wafer 20 may be enclosed, for example in a quartz envelope.

Referring to FIG. 4c, a thermal step causes monocrystalline silicon lamina 40 to cleave from the donor wafer at the cleave plane. Cleaving is achieved in this example by exfoliation, which may be achieved at temperatures between, for example, about 350 and about 650 degrees C., for example, about 550 degrees C. In general, exfoliation proceeds more rapidly at higher temperature. During cleaving, light pressure may be applied to donor wafer 20. Pressures in the range of about 1 to about 100 psi, for example 40 psi, could be applied. The thickness of lamina 40 is determined by the depth of cleave plane 30. In many embodiments, the thickness of lamina 40 is between about 1 and about 10 microns, for example between about 2 and about 5 microns, for example about 4.5 microns. In other embodiments, the thickness of lamina 40 is between about 4 and about 20 microns, for example between about 10 and about 15 microns, for example about 11 microns. Second surface 62 is created by cleaving.

An anneal step may be performed to repair damage caused to the crystal lattice throughout the body of lamina 40 during the implant step Annealing may be performed while lamina 40 remains in place on vacuum chuck 54, for example, at 500 degrees C. or greater, for example at 550, 600, 650, 700, 800, 850 degrees C. or greater, at about 950 degrees C. or more; this anneal is for at least 30 seconds. The structure may be annealed, for example, at about 650 degrees C. for about 45 minutes, or at about 800 degrees for about ten minutes, or at about 950 degrees for 120 seconds or less. In many embodiments the temperature exceeds 900 degrees C. for at least 60 seconds.

Next lamina 40 is removed from vacuum chuck 54. This may be done, for example, using a vacuum paddle (not shown). To affect this transfer, the vacuum paddle is placed on second surface 62, while the vacuum on first surface 10 is released. Following transfer to the vacuum paddle, second surface 62 is held by vacuum, while first surface 10 is exposed. Referring to FIG. 4d, lamina 40 is then transferred from the vacuum paddle to a temporary carrier 50. It is affixed to temporary carrier 50, for example using an adhesive (not shown). This adhesive must tolerate moderate temperature and must be readily releasable. Suitable adhesives include, for example, polyester with maleic anhydride and rosin, which is hydrocarbon-soluble; or polyisobutylene and rosin, which is detergent soluble. Temporary carrier 50 may be any suitable material, for example glass, metal, polymer, silicon, etc. Following transfer, first surface 10 will be held to temporary carrier 50 by adhesive, while second surface 62 is exposed. Low heat, for example to about 200 degrees C., may optionally be briefly applied to flow the adhesive; the structure is then cooled.

An etch step to remove damage caused by exfoliation may be performed, for example by a mix of hydrofluoric (HF) acid and nitric acid, or using KOH. It may be found that annealing is sufficient to remove all or nearly all damage and this etch is unnecessary. At minimum, the surface is cleaned of organic materials and residual oxide, using a dilute HF solution; for example, 10:1 HF for two minutes. In some embodiments, a conventional SC-1 clean may precede the HF dip.

Following this wet process, the lamina 40 and support element 50 are heated to what will be the PECVD temperature. Heating may be a two-step process, with a pre-heat to a first temperature under a heat lamp, and heating to deposition temperature performed in a PECVD chamber. Deposition temperature may be between about 80 and about 150 degrees C., for example less than about 120 degrees C., for example between about 90 and about 110 or 120 degrees C. In the present embodiment, an undoped amorphous silicon layer 74 is deposited on and immediately in contact with second surface 62. Hydrogen and silane are flowed and the plasma is struck. The H2:SiH₄ ratio is between about 1:1 and about 100:1, for example between about 4:1 and about 10:1, in one embodiment about 5:1. An inert gas such as argon or helium may be flowed as well. The thickness of undoped layer 74 may be as desired, for example between about 20 and about 200 angstroms. In embodiments this thickness may be less than about 100 angstroms, for example between about 30 and about 80 angstroms, for example about 50 angstroms. Note that in this embodiment, layer 74 is silicon, so the precursor gas is silane. If layer 74 is a different material, clearly the precursor gas will be different. For example, if layer 74 is germanium, the precursor gas will be germane.

Deposition of undoped silicon layer 74 is immediately followed by deposition of heavily doped silicon layer 72. Conditions for deposition of heavily doped silicon layer 72 may be the same as for undoped layer 74, though during deposition of layer 72 a dopant gas is flowed as well. In this example, layer 72 is heavily doped with an n-type dopant; thus the dopant gas may be, for example, PH₃, which will provide phosphorus, though arsenic or some other n-type dopant may be used instead. The thickness of layer 72 may be as desired, for example between about 30 and about 300 angstroms. In some embodiments, thickness may be less than about 300 angstroms, for example between about 50 and about 200 angstroms, for example between about 80 and about 100 angstroms, for example about 80 angstroms. Lightly doped n-type lamina 40 will comprise the base region of the photovoltaic cell to be formed, and heavily doped amorphous n-type silicon layer 72 provides electrical contact to the base region. Layer 74 is sufficiently thin that it does not impede electrical connection between lamina 40 and heavily doped silicon layer 72.

In the present example, layers 74 and 72 are amorphous silicon. In alternative embodiments, one or both of these layers may be other materials, including germanium, silicon germanium, silicon oxide, or silicon carbide. In alternative embodiments, either or both of layers 74 and 72 can be nanocrystalline or microcrystalline instead of amorphous. Degree of crystallinity is improved by increasing hydrogen dilution, plasma power, or both.

A TCO layer 110 is formed on and in immediate contact with amorphous silicon layer 72. Appropriate materials for TCO 110 include indium tin oxide and aluminum-doped zinc oxide. This layer may be, for example, about between about 500 and about 1500 angstroms thick, for example about 750 angstroms thick. This thickness will enhance internal reflection from a reflective layer to be deposited. In some embodiments, this layer may be substantially thinner, for example about 100 to about 200 angstroms.

As will be seen, in the completed device, incident light will enter lamina 40 at first surface 10. After passing through lamina 40, light that has not been absorbed will exit lamina 40 at second surface 62, then pass through amorphous layers 74 and 72, and through TCO layer 110. A reflective layer 12 formed on TCO layer 110 will reflect this light back into the cell for a second opportunity to be absorbed, improving efficiency. A conductive, reflective metal may be used for reflective layer 12. Various layers or stacks may be used. In one embodiment, reflective layer 12 is formed by depositing a very thin layer of chromium, for example about 30 or 50 angstroms to about 100 angstroms, on TCO layer 110, followed by about 1000 to about 3000 angstroms of silver. In an alternative embodiment, not pictured, reflective layer 12 may be aluminium, having a thickness of about 1000 to about 3000 angstroms. In the next step, a layer will be formed by plating. Conventional plating cannot be performed onto an aluminum layer, so if aluminum is used for reflective layer 12, an additional layer or layers must be added to provide a seed layer for plating. In one embodiment, for example, a layer of titanium, for example between about 200 and about 300 angstroms thick, is formed on the aluminum layer, followed by a seed layer, for example of cobalt, which may have any suitable thickness, for example about 500 angstroms.

Metal support element 60 is formed by plating on reflective layer 12 (a chromium/silver stack in this embodiment). To form metal support element 60 by electroplating, temporary carrier 50 and lamina 40, and associated layers, are immersed in an electrolyte bath. An electrode is attached to reflective layer 12, and a current passed through the electrolyte. Ions from the electrolyte bath build up on reflective layer 12, forming metal support element 60. Metal support element 60 may be, for example, an alloy of nickel and iron. Iron is cheaper, while the coefficient of thermal expansion of nickel is better matched to that of silicon, reducing stress during later steps. The thickness of metal support element 60 may be as desired. Metal support element 60 should be thick enough to provide structural support for the photovoltaic cell to be formed. A thicker support element 60 is less prone to bowing. In contrast, minimizing thickness reduces cost. One skilled in the art will select a suitable thickness and iron:nickel ratio to balance these concerns. Thickness may be, for example, between about 25 and about 100 microns, for example about 50 microns. In some embodiments, the iron-nickel alloy is between about 55 and about 65 percent iron, for example 60 percent iron. Additional detail regarding fabrication of permanent support element 60 can be found in Murali et al., earlier incorporated.

Additional layers may be formed on or over deposited semiconductor layers 74 and 72 before construction of support element 60; in general support element 60 is constructed on doped layer 72 with zero, one, or more layers intervening.

Turning to FIG. 4e, following construction of metal support element 60, temporary carrier 50 can be removed, exposing first surface 10. FIG. 4e shows the structure inverted, with metal support element 60 on the bottom, as it will be during operation. Lamina 40 is released from temporary support element 50. In some embodiments, heating, for example to about 225 C, will cause the adhesive to soften, aiding removal. First surface 10 is cleaned, for example using a detergent, followed by a rinse. In some case a solvent may be used, such as photoresist stripper. Temporary support element 50 is also cleaned, using the same methods, and subsequently re-used.

First surface 10 is cleaned of native oxide. This clean may be performed using a dilute HF solution; for example, 10:1 HF for two minutes. Following cleaning, undoped amorphous silicon layer 78 is deposited on and immediately in contact with first surface 10. Its thickness may be as desired, for example between about 20 and about 200 angstroms. In embodiments this thickness may be less than about 100 angstroms, for example between about 30 and about 80 angstroms, for example about 50 angstroms. Next heavily doped layer 76 is deposited on and in contact with undoped layer 78. The thickness of layer 76 may be less than about 300 ansgtroms, for example between about 50 and about 200 angstroms, for example between about 80 and about 100 angstroms, for example about 80 angstroms. Layers 78 and 76 may be deposited by PECVD at a temperature below about 150 degrees C. with hydrogen dilution, or more conventional conditions may be used. In this example, heavily doped silicon layer 76 is heavily doped p-type, opposite the conductivity type of lightly doped n-type lamina 40, and serves as the emitter of the photovoltaic cell. The term “heavily doped” when referring to amorphous silicon layers can be considered to mean doped to at least 10¹⁸ dopant atoms/cm³. In alternate embodiments, either or both of layers 76 and 78 may be nanocrystalline or amorphous, or may be some other suitable material, such as germanium, silicon-germanium, silicon carbide, or silicon oxide.

A transparent conductive oxide (TCO) layer 112 is formed on and in immediate contact with amorphous silicon layer 76. Appropriate materials for TCO 112 include indium tin oxide and aluminum-doped zinc oxide. This layer may be, for example, about between about 700 to about 1800 angstroms thick, for example about 900 angstroms thick. In some embodiments, a layer having a refractive index between that of amorphous silicon layer 76 and TCO layer 112, may be formed on amorphous silicon layer 76, as described in Liang et al., U.S. patent application Ser. No. 12/894,254, “A Semiconductor with a Metal Oxide Layer Having Intermediate Refractive Index,” filed Sep. 30, 2010, owned by the assignee of the present application and hereby incorporated by reference.

Metal lines 57, for example of silver paste, may be formed on TCO layer 112, for example by screen printing, and cured at a relatively low temperature, for example about 180-250 degrees C.

A photovoltaic cell has been formed, including lightly doped n-type lamina 40, which comprises the base of the cell, and heavily doped p-type amorphous silicon layer 76, which serves as the emitter of the cell. Heavily doped n-type amorphous silicon layer 72 will provide good electrical contact to the base region of the cell. Electrical contact must be made to both faces of the cell. Contact to amorphous silicon layer 76 is made by gridlines 57, by way of TCO layer 112. Metal support element 60 is conductive and is in electrical contact with base contact 72 by way of conductive layer 12 and TCO layer 110.

FIG. 4e shows completed photovoltaic assembly 80, which includes a photovoltaic cell and metal support element 60. In alternative embodiments, by changing the dopants used, heavily doped amorphous silicon layer 72 may serve as the emitter, while heavily doped silicon layer 76 serves as a contact to the base region. Incident light (indicated by arrows) falls on TCO 112, enters the cell at heavily doped p-type amorphous silicon layer 76, enters lamina 40 at first surface 10, and travels through lamina 40, leaving lamina 40 at second surface 62, and travelling through amorphous silicon layers 78 and 76, and TCO layer 110. Reflective layer 12 will serve to reflect some light back into the cell. Permanent support element 60 serves as a substrate. Support element 60 and lamina 40, and associated layers, form a photovoltaic assembly 80. Multiple photovoltaic assemblies 80 can be formed and affixed to a supporting substrate 90 or, alternatively, a supporting superstrate (not shown). Each photovoltaic assembly 80 includes a photovoltaic cell. The photovoltaic cells of a module are generally electrically connected in series.

What has been described is a method for forming a photovoltaic cell, the method comprising: providing a monocrystalline silicon lamina having a first surface and a second surface opposite the first, the lamina having a thickness between about 1 and about 20 microns, the first surface adhered to a first support element by an adhesive; depositing a first undoped amorphous, nanocrystalline, or microcrystalline semiconductor layer on and in contact with the second surface of the lamina by PECVD while flowing a precursor gas, the first undoped layer having a thickness less than about 100 angstroms; depositing a second doped amorphous, nanocrystalline, or microcrystalline semiconductor layer on and in contact with the first undoped layer by PECVD while flowing the precursor gas, the second doped layer having a thickness less than about 300 angstroms, wherein, during the step of depositing the first undoped layer and the step of depositing the second doped layer, deposition temperature is less than about 150 degrees C. and a ratio of hydrogen to the precursor gas is at least 4:1, and wherein the lamina, the first undoped layer, and the second doped layer are suitable for use in a photovoltaic cell.

In the embodiments just described, texturing was performed at first surface 10 before exfoliation. In other embodiments, texturing may be performed following exfoliation and construction of permanent support element 60 by plating. The texturing method of Li et al. calls for a buffing step thought to introduce surface stress, which creates nucleation points for etching. When texturing is performed following plating, it may be found that the stress induced by plating may render the buffing step unnecessary, and a timed etching step with a selective etchant such as TMAH or KOH or NaOH may be sufficient to form pyramids having a peak-to-valley height less than one micron.

Referring to FIG. 4e, in the detailed example just provided, a lightly n-doped monocrystalline silicon lamina 40 serves as the base region of the photovoltaic cell, while a heavily doped n-type amorphous silicon layer 72 provides electrical contact at the back of the cell and a heavily doped p-type amorphous silicon layer 76 serves as the emitter of the cell at the front, light-facing surface. The conductivity types may be varied. All may be reversed, forming a cell having a lightly doped p-type base, a heavily doped n-type emitter at the front surface of the cell, and a heavily doped p-type contact at the back of the cell. Alternatively, the emitter may be formed at the back of the cell, where the heavily doped region at the front provides electrical contact.

In the example provided, the original surface 10 of the donor wafer is at the front, light-facing surface of the completed cell, while the second surface 62, which was created by cleaving, is nearer the back of the cell. In alternative embodiments, first surface 10 may be at the back of the cell, while second surface 62 is at the front of the cell.

A variety of embodiments has been provided for clarity and completeness. Clearly it is impractical to list all possible embodiments. Other embodiments of the invention will be apparent to one of ordinary skill in the art when informed by the present specification. Detailed methods of fabrication have been described herein, but any other methods that form the same structures can be used while the results fall within the scope of the invention.

The foregoing detailed description has described only a few of the many forms that this invention can take. For this reason, this detailed description is intended by way of illustration, and not by way of limitation. It is only the following claims, including all equivalents, which are intended to define the scope of this invention.

What is claimed is:

1. A method for forming a device, the method comprising:
providing a monocrystalline semiconductor lamina having a first surface and a second surface opposite the first;
depositing a first undoped amorphous, nanocrystalline, or microcrystalline semiconductor layer on and in contact with the second surface of the lamina by PECVD while flowing a precursor gas, the first undoped layer having a thickness less than about 100 angstroms;
depositing a second doped amorphous, nanocrystalline, or microcrystalline semiconductor layer on and in contact with the first undoped layer by PECVD while flowing the precursor gas, the second doped layer having a thickness less than about 300 angstroms,
wherein, during the step of depositing the first undoped layer and the step of depositing the second doped layer, deposition temperature is less than about 150 degrees C. and a ratio of hydrogen to the precursor gas is at least 1:1; and
wherein the lamina, the first undoped layer, and the second doped layer are suitable for use in a photovoltaic cell.

2. The method of claim 1 further comprising forming the photovoltaic cell, the cell comprising the lamina, the first undoped layer, and the second doped layer.

3. The method of claim 2 wherein the lamina has a thickness between about 1 and about 20 microns.

4. The method of claim 3 wherein the lamina has a thickness between about 3 and about 12 microns.

5. The method of claim 2 wherein the deposition temperature is less than about 120 degrees C.

6. The method of claim 5 wherein the deposition temperature is between about 90 degrees C. and about 110 degrees C.

7. The method of claim 2 wherein, during the step of depositing the first undoped layer and the step of depositing the second doped layer, the first surface of the lamina is adhered to a support element by an adhesive.

8. The method of claim 7 wherein the support element is a temporary support element not present in the completed photovoltaic cell.

9. The method of claim 2 further comprising:
depositing a third undoped amorphous, nanocrystalline, or microcrystalline semiconductor layer on and in contact with the first surface of the lamina, the third undoped layer having a thickness less than about 100 angstroms; and
depositing a fourth doped amorphous, nanocrystalline, or microcrystalline semiconductor layer on and in contact with the third undoped layer, the fourth doped layer having a thickness less than about 300 angstroms.

10. The method of claim 9 wherein the second doped layer is doped to a first conductivity type, and the fourth doped layer is doped to a second conductivity type opposite the first conductivity type.

11. The method of claim 9 wherein either the second doped layer or the fourth doped layer is an emitter of the photovoltaic cell, and wherein the lamina comprises a base region of the photovovoltaic cell.

12. The method of claim 2 wherein the first undoped layer or the second doped layer is amorphous silicon or amorphous silicon oxide or amorphous silicon carbide.

13. The method of claim 2 wherein the first undoped layer or the second doped layer is nanocrystalline silicon or nanocrystalline silicon oxide or nanocrystalline silicon carbide.

14. The method of claim 2 wherein the first undoped layer or the second doped layer is microcrystalline silicon or microcrystalline silicon oxide or microcrystalline silicon carbide.

15. The method of claim 2 wherein the ratio of hydrogen to the precursor gas is at least 4:1.

16. The method of claim 15 wherein the precursor gas is silane.

17. The method of claim 2 wherein the ratio of hydrogen to the precursor gas is at least 8:1.

18. A method for forming a device, the method comprising:
providing a monocrystalline silicon lamina having a first surface and a second surface opposite the first, the lamina having a thickness between about 1 and about 20 microns, the first surface adhered to a first support element by an adhesive;
depositing a first undoped amorphous, nanocrystalline, or microcrystalline semiconductor layer on and in contact with the second surface of the lamina by PECVD while flowing a precursor gas, the first undoped layer having a thickness less than about 100 angstroms;
depositing a second doped amorphous, nanocrystalline, or microcrystalline semiconductor layer on and in contact with the first undoped layer by PECVD while flowing the precursor gas, the second doped layer having a thickness less than about 300 angstroms,
wherein, during the step of depositing the first undoped layer and the step of depositing the second doped layer, deposition temperature is less than about 150 degrees C. and a ratio of hydrogen to the precursor gas is at least 4:1, and
wherein the lamina, the first undoped layer, and the second doped layer are suitable for use in a photovoltaic cell.

19. The method of claim 18 further comprising forming the photovoltaic cell, wherein the photovoltaic cell comprises the lamina, the first undoped layer, and the second doped layer.

20. The method of claim 19 wherein the step of providing the monocrystalline silicon lamina comprises:
defining a cleave plane within a monocrystalline silicon donor wafer; and
cleaving the lamina from the donor wafer at the cleave plane.

21. The method of claim 20 further comprising, following the step of cleaving the lamina from the donor wafer at the cleave plane, annealing the lamina at a temperature of at least 850 degrees C. for at least 30 seconds.

22. The method of claim 19 further comprising constructing a permanent support element on the second doped layer, with zero, one, or more layers intervening.

23. The method of claim 22 wherein the permanent support element comprises metal and is formed by plating.

24. The method of claim 19 further comprising:
releasing the first surface from the first support element;
depositing a third undoped amorphous, nanocrystalline, or microcrystalline semiconductor layer on and in contact with the first surface of the lamina, the third undoped layer having a thickness less than about 100 angstroms; and
depositing a fourth doped amorphous, nanocrystalline, or microcrystalline semiconductor layer on and in contact with the third undoped layer, the fourth doped layer having a thickness less than about 300 angstroms.

25. The method of claim 24 wherein the second doped layer or the fourth doped layer is an emitter of the photovoltaic cell, and wherein the lamina comprises a base region of the photovoltaic cell.

26. The method of claim 19 wherein the ratio of hydrogen to the precursor gas is at least 8:1.

27. The method of claim 19 wherein the precursor gas is silane.
